(19) United States
(12) Patent Application Publication
(10) Pub. No.: US 2016/0205785 A1
(43) Pub. Date: Jul. 14, 2016

(54) METHOD FOR POSITIONALLY STABLE SOLDERING

(71) Applicant: ZIZALA LICHTSYSTEME GMBH, Wieselburg (AT)

(72) Inventors: Dietmar KIESLINGER, Theresienfeld (AT); Peter WURM, Eisenstadt (AT)

(21) Appl. No.: 14/911,895

(22) PCT Filed: Sep. 3, 2014
(86) PCT No.: PCT/AT2014/050194

§ 371 Date: Feb. 12, 2016

(30) Foreign Application Priority Data
Sep. 3, 2013 (AT) A 50541/2013

(51) Int. Cl. H05K 3/30; H05K 1/18; H05K 3/34

(52) U.S. Cl. CPC H05K 3/305; H05K 3/341; H05K 1/181; H05K 2201/10106

(57) ABSTRACT

A method for positionally stable soldering of at least one component part contact face (11) of an electronic component part (1) to at least one corresponding carrier plate contact face (12) of a carrier plate (2), said method having the following steps:
a) mounting at least two adhesive points (3a, 3b, 8a, 8b, 9a, 9b) on the carrier plate (2), wherein the position of each adhesive point (3a, 3b, 8a, 8b, 9a, 9b) is predefined,
b) fitting the printed carrier plate (2) with the at least one electronic component part (1), wherein the position of the adhesive points (3a, 3b, 8a, 8b, 9a, 9b) is predefined in step a) in such a way that the at least one electronic component part (1) contacts the at least two adhesive points (3a, 3b, 8a, 8b, 9a, 9b) substantially in an edge region formed by the at least one side face (5a, 5b, 5c, 5d) and the lower face 6 and the at least one component part contact face (11) at least partially overlaps the at least one carrier plate contact face (12),
c) waiting for completion of a curing process of the adhesive points (3a, 3b, 8a, 8b, 9a, 9b) for a predefinable period of time t,
d) heating the solder material (13) in order to establish an electrical, mechanical and/or thermal connection between the at least one component part contact face (11) and the at least one carrier plate contact face (12).

The invention relates to a method for positionally stable soldering of at least one component part contact face of an electronic component part to at least one corresponding carrier plate contact face of a carrier plate, wherein the at least one electronic component part has a lower and upper face and also at least one side face connecting the lower face to the upper face, wherein the component part contact face is formed on the lower face and the carrier plate contact face at least partly has solder material, wherein the electronic component part is preferably an optoelectronic component part.

The invention also relates to a carrier plate having at least one electronic component part having at least one component part contact face, wherein the carrier plate has at least one carrier plate contact face corresponding to said component part contact face, wherein the at least one electronic component part has a lower and upper face and also at least one side face connecting the lower face to the upper face, wherein the component part contact face is formed on the lower face and the at least one carrier plate contact face at least partly has solder material.

The mounting of electronic component parts on carrier plates, for example on printed circuit boards, is a process that is very often necessary in the production of electrical circuits. Printed circuit boards in this case generally have conductive tracks, which interconnect individual or multiple terminal contacts, wherein individual electronic component parts are connected to the electrical terminal contacts. The connection may have a number of aspects, such as an electrical, mechanical and/or thermal connection.

Different methods have been known from the prior art, with the aid of which a connection between an electronic component part and a carrier plate can be realised. By way of example, contact faces of individual electronic component parts can thus be soldered to contact faces arranged on the carrier plates.

At this juncture, reference is made to the SMT (surface mount technology) method, in which the electrical terminals or contact faces of the electronic component part as well as the corresponding contact faces of the carrier plate are located on the surface of said electronic component part and said carrier plate respectively and the electronic component parts merely have to be secured on the surface of the carrier plate, it being possible to dispense with the provision of through-bores. The contact faces of the carrier plate are in this case firstly coated with a solder agent, usually a solder paste. The carrier plate is then fitted with individual electronic component parts.

In order to produce a permanent electrical and/or thermal and/or mechanical connection between the electronic component parts and the carrier plate, the reflow soldering method has been known by way of example, in which the solder paste and the contact faces, following the fitting of the carrier plate with the electronic component parts, are heated in such a way that the solder paste melts and combines with the contact faces of the carrier plate and of the respective electronic component part.

Typical electronic component parts weigh only a few milligrams. On account of the high density of the molten solder (the solder paste), the electronic component parts float on the molten solder. Due to the surface tension of the liquid solder and any flux residues possibly present, minimal forces may be effective, which can cause a displacement, rotation or swimming of individual electronic component parts into a position that is often stable, but usually difficult to predict.

This displacement, rotation or swimming (“floating into position”) does not generally constitute a problem for the electrical connection. Rather, this effect is even utilised to fix slightly misplaced electronic component parts.

For applications in which it is important to accurately maintain a target position of these electronic component parts with respect to the carrier plate, this process of floating into position may cause inadmissible deviations from the respective target position.

A method with the aid of which the position of individual electronic component parts can be determined already before the soldering process consists in fixedly clamping the component parts mechanically, for example by means of screw and/or clamp connections. However, the provision of such screw and/or clamp connections presupposes the presence of mechanical engagement points on the carrier plates and the electronic component parts, whereby the miniaturisation of the electronic component parts and/or the density of the fitting of the carrier plate are subject to limits. Even conventional pre-gluing methods, in which the adhesive is applied to the underside of the electronic component parts and with which electronic component parts can thus be glued to a carrier plate, presuppose the presence of free adhesive faces on the underside of the electronic component part. This is often not the case, in particular when the underside of the electronic component parts is formed substantially completely from contact faces.

The object of the invention is therefore to create a method for positionally stable soldering of the type mentioned in the introduction, which method can be easily carried out, allows a space-saving arrangement of the electronic component parts, and nevertheless enables a permanently stable electrical, mechanical and/or thermal connection of the electronic component parts to a carrier plate. An optoelectronic component part is understood to mean electronic component parts that can convert electrical signals into light and/or can convert light into electrical signals, wherein the term light is understood to mean electromagnetic waves having a wavelength of preferably 100 nm to 1 cm, preferably 400 nm to 700 nm. Examples include electrical component parts such as LEDs, laser diodes, diode lasers, super emitters, photodiodes, or any other optical electronic components.

This object is achieved with a method of the type mentioned in the introduction, said method comprising the following steps in accordance with the invention:
a) mounting at least two adhesive points on the carrier plate, wherein the position of each adhesive point is predefined,
b) fitting the printed circuit board/carrier plate with the at least one electronic component part, wherein the position of the adhesive points is predefined in step a) in such a way that the at least one electronic component part contacts the at least two adhesive points substantially in an edge region formed by the at least one side face and the lower face and the at least one component part contact face at least partially overlaps the at least one carrier plate contact face,
c) waiting for completion of a curing process of the adhesive points for a predefinable period of time t,
d) heating the solder material in order to establish an electrical, mechanical and/or thermal connection between the at least one component part contact face and the at least one carrier plate contact face.

Thanks to the method according to the invention it is possible to mount an individual or multiple electronic component parts on a carrier plate, typically a printed circuit board, in a positionally stable manner and to prevent any shifting or swimming of individual electronic component parts during the soldering process and at the same time to enable a dense arrangement of the electronic component parts. In addition, the method according to the invention can be carried out easily and economically and enables a permanently stable electrical, mechanical and/or thermal connection between the electronic component parts and the carrier plate. This method can be used for known soldering methods, such as the reflow soldering or the wave soldering method. The term electronic component parts is understood to mean any electrical elements, by way of example resistors, coils, capacitors, transistors, sensors or diodes, in particular electronic component parts that have to adopt an exact position on a carrier plate (for example LEDs in optical modules). Such component parts and carrier plates are used for example in vehicles (as “vehicle electronics”), in particular in vehicle headlights (“head-light electronics”). Especially in the case of headlight modules, the exact positioning and contacting of the light sources (which are increasingly formed as light-emitting diodes or semiconductor laser diodes in SMD design) has become increasingly important. The component part contact face may match the carrier plate contact face in terms of shape and size. The component part contact face may also overlap the carrier plate contact face up to 20, 30, 40, 50, 60, 70, 80, 90% or completely (thus covering the carrier plate contact face).

The carrier plate contact face is preferably coated with a solder material, which is plastically deformable before (and preferably also during) melting thereof, such that the position of a component part in electrical contact with the carrier plate contact face can be changed without interrupting the electrical contact. It is thus possible to change the height of the component part with respect to the carrier plate contact face without interrupting the electrical contact. It has proven to be particularly advantageous when the solder material is applied to the carrier by means of screen printing, since the coplanarity between individual solder deposits is thus ensured and the component part can be placed parallel to the carrier plate.

The swimming of the electronic component parts at a solder position is dependent on (more specifically related to) the component part weight and the expansion (area) of the carrier plate contact face. Typical electronic component parts that are to be soldered by means of the method according to the invention have a weight of at least 10 mg up to a few grams (for example thin quad flat packs), for example 10 g. The ratio of component part weight to electrically effective contact face is advantageously between 1 mg/mm², in any case preferably less than 50 mg/mm², and particularly preferably less than 10 mg/mm². The electrically effective contact face is in this case the face with which the electronic component part electrically contacts the carrier plate. Here, it is irrelevant whether or not the electrically effective contact face is electrically continued at the carrier plate to other component parts or contacts. The electrically effective contact face may therefore serve to electrically connect the electronic component part to other electronic component parts located on the carrier plate or connected thereto and/or to mechanically stabilise the electronic component part on the carrier plate and/or to dissipate heat from the electronic component part into the carrier plate. The carrier plate contact face has the solder material preferably already before step b) is carried out, particularly preferably before step a) is carried out.

In an advantageous embodiment of the method according to the invention the adhesive points are arranged in such a way that a virtual straight line of connection between the adhesive points forms a straight line through the centre point of the lower face of the at least one electronic component part. This allows a particularly simple and at the same time stable fixing of the at least one electronic component part.

In addition, in a favourable development of the method according to the invention, the adhesive points may be arranged in such a way that an adhesive point is arranged at each corner of the at least one electronic component part. By way of example, two adhesive points can be arranged at opposite corners of the electronic component part. The expression “corner of the electronic component part” is understood to mean an area at which the course of an edge of the electronic component part formed between the side face and the lower face changes in such a way that a corner is formed. Alternatively, the electronic component parts may also have a rounded, in particular a circular lower face. By way of example, LED SMDs (surface mounted devices) having a circular lower face are known, wherein the adhesive points are mounted on the edge formed between the lower face and the side face of these electronic component parts.

A particularly stable connection of the electronic component part to the carrier plate can be realised by providing a corresponding adhesive point at each corner of the electronic component part. The electronic component part preferably has a rectangular design, whereby in this case a total of four adhesive points can be mounted at corners of the electronic component part.

In accordance with a development of the method according to the invention three adhesive points can be provided, of which the virtual straight lines of connection form an equilateral triangle, wherein the centroid of this equilateral triangle coincides with the centre point of the lower face. The stability of the adhesive connection between the electronic component part and the carrier plate can thus be increased efficiently and economically.

In a particularly favourable embodiment of the method according to the invention the at least two adhesive points may consist of a heat-curing adhesive material, wherein the temperature necessary for the heat curing lies below the melting point of the solder material. This ensures the production of a positionally stable connection between the at least one electronic component part and the carrier plate, already before the solder material has melted, whereby a displacement, rotation or swimming of the at least one electronic component part can be reliably prevented. Alternatively, any other adhesive methods and adhesive materials can also be used. It is important that the adhesive connections are sufficiently cured before the initiation of the melting process of the solder material.

In a development of the method the adhesive points may be arranged in positions that in step c) are exposed to a heat curing and in so doing are exposed to substantially identical thermal conditions. The term “substantially identical thermal conditions” is understood within the scope of this application to mean a maximum admissible temperature difference of at most 10° C., preferably at most 5° C., between the individual adhesive points during the heat curing process.

In accordance with a further advantageous embodiment of the method according to the invention the volume of the adhesive points may be predefinable in step a). The volume of the adhesive points can be influenced in a simple manner by a purposeful metering of the adhesive quantity applied per adhesive point. The method can thus be easily adapted to the requirements and dimensions of individual electronic component parts.

In a first variant of the method according to the invention a solder stop mask applied to the (printed circuit board surface) carrier plate surface may cover an edge region of the at least one carrier plate contact face, and in step a) adhesive points can be mounted in this edge region on the solder stop mask. The adhesion and the height of the adhesive points can thus be purposefully influenced.

In an alternative second variant of the method according to the invention a solder stop mask applied to the printed circuit board surface/carrier plate surface may end before an edge region of the at least one carrier plate contact face, and in step a) adhesive points may be mounted in this edge region on the solder stop mask. The adhesion and the height of the adhesive points can thus be purposefully influenced.

The statements regarding the adhesive points, unless specified otherwise, always relates to an individual electronic component part. If a plurality of electronic component parts are fixed in accordance with methods according to the invention, the adhesive points are for this purpose mounted on the respective electronic component part in the manner described above.

In order to enable a feed and return of an electrical connection of the at least one electronic component part to the carrier plate, the at least one electronic component part has at least two or three component part contact faces and at least two or three corresponding carrier plate contact faces in accordance with a favourable variant of the method according to the invention. The at least two component part contact faces are electrically insulated from one another (apart from the electrical connection fed by the contact faces and necessary for the component part function) and the at least two corresponding carrier plate contact faces are electrically insulated from one another—a circuit can therefore close via corresponding contact faces (of the carrier plate and of the at least one electronic component part) via the at least one electronic component part. A third contact face (component part and carrier contact face) can be provided by way of example in order to enable a transfer of heat from the electronic component part to the carrier plate. The carrier plate for this purpose could be fitted with a heat sink or could also be formed as a heat sink.

In a particularly favourable embodiment of the method according to the invention the at least one electronic component part may be an LED. The direction of emission and position of the LED can thus be defined particularly accurately.

A particularly space-saving arrangement of the at least one electronic component part can be achieved if the at least one electronic component part is an SMD component part, in particular an SMD component part without protruding terminal pins or component part contact faces (“flat no lead” component part).

The ratio of the weight of the at least one electronic component part to the electrically effective contact face may advantageously be less than 50 mg/mm², preferably less than 10 mg/mm². The electrically effective contact face is the face via which the electronic component part electrically contacts the carrier plate.

A further aspect of the invention concerns a carrier plate of the type mentioned in the introduction, wherein the carrier plate has at least two adhesive points, wherein the position of each adhesive point is predefinable, wherein the carrier plate is fitted with the at least one electronic component part, wherein the electronic component part is preferably an optoelectronic component part, wherein the position of the adhesive points can be predefined in such a way that the at least one electronic component part contacts the at least two adhesive points substantially in an edge region formed by the at least one side face and the lower face and the at least one component part contact face partially overlaps the at least one carrier plate contact face, wherein the adhesive points are configured to change from an uncured state receiving the electronic component part into a cured state mechanically stabilising the electronic component part, wherein the at least one component part contact face can be electrically, mechanically and/or thermally connected to the at least one carrier plate contact face by heating the solder material.

The invention together with further embodiments and advantages is explained in greater detail hereinafter on the basis of an exemplary, non-limiting embodiment, which is illustrated in the drawings, in which

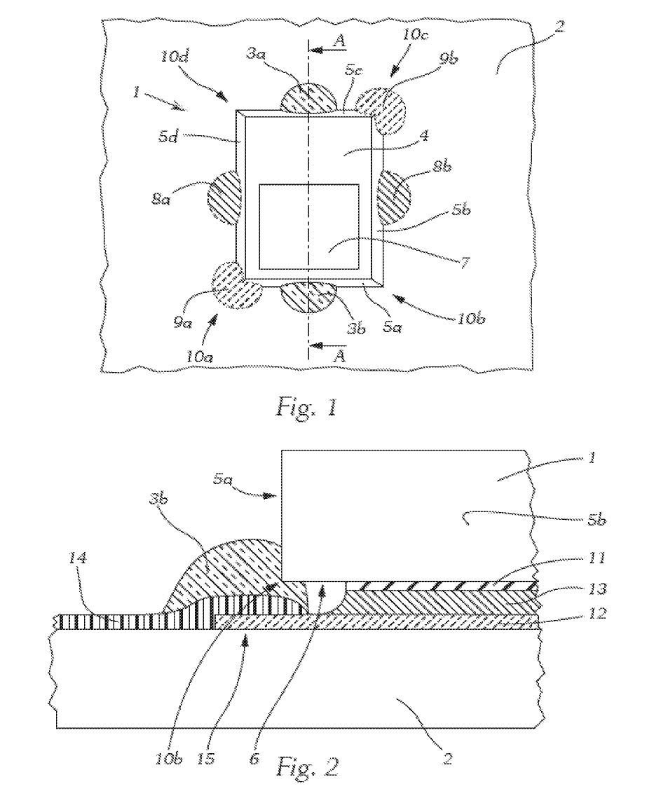

FIG. 1 shows a plan view of an electronic component part adhered on a carrier plate,

FIG. 2 shows a detail of a sectional illustration of a first variant of an adhesive connection between the electronic component part and the carrier plate in accordance with the line of section AA in FIG. 1,

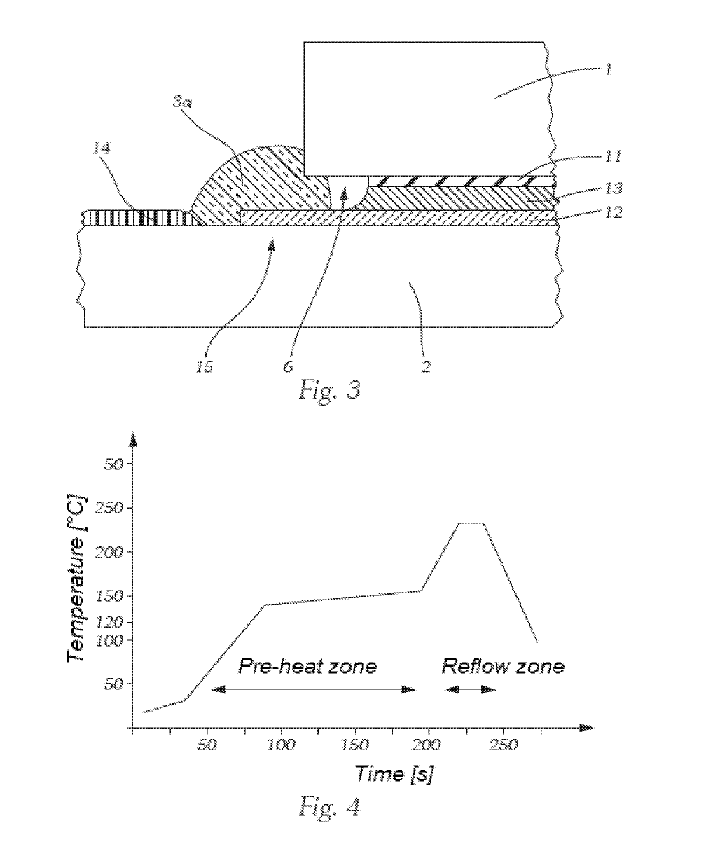

FIG. 3 shows a detail of a sectional illustration of a second variant of an adhesive connection between the electronic component part and the carrier plate in accordance with the line of section AA in FIG. 1,

FIG. 4 shows a schematic illustration of a temperature profile, and

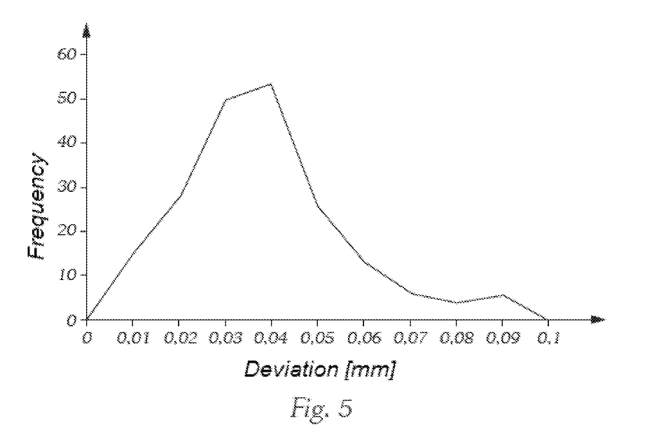

FIG. 5 shows an exemplary illustration of a probability distribution function of a radial position error of an electronic component part secured with the aid of the method according to the invention.

FIG. 1 shows an electronic component part 1, wherein the electronic component part is an optoelectronic component part, in a plan view, which is secured to a portion of a carrier plate 2 with the aid of two adhesive points 3a, 3b (the adhesive points 3a and 3b were applied beforehand to the carrier plate 2 and the carrier plate 2 was then fitted with the electronic component part 1; the adhesive points 3a and 3b could theoretically also be applied to the carrier plate once said carrier plate has been fitted with the electronic component part 1, however there is the risk that the electronic component part 1 will be shifted in its position as a result of the application of the adhesive and resultant forces). The electronic component part 1 has a substantially rectangular form and is delimited by an upper face 4, four side faces 5a, 5b, 5c and 5d, and a lower face 6 (see FIGS. 2 and 3), which extends, opposite the upper face 4, between the four side faces 5a to 5d. The electronic component part 1 has, on the upper face 4, a coupling face 7. The electronic component part 1 may be, for example, a sensor or an LED, wherein the coupling face 7 by way of example may be a sensor face for receiving external signals (light, temperature etc.) or a light emission face, for example of an LED. The adhesive points 3a and 3b are arranged in such a way that a virtual straight line of connection (which coincides in the shown example with the line of section AA) between the adhesive points divides the electronic component part 1 into two halves of equal size and the straight line of connection thus intersects a virtual centre point of the lower face 6.

In addition, alternative variants of adhesive point arrangements are indicated in FIG. 1. Two adhesive points 8a and 8b could thus be provided, which correspond substantially to a 90° rotation of the adhesive points 3a and 3b. Alternatively, adhesive points 9a and 9b could be provided which are arranged at corners 10a and 10c of the electronic component part 1, wherein a virtual straight line of connection through these corners 10a and 10c intersects the virtual centre point of the lower face 6. In a further variant each corner 10a, 10b, 10c, 10d could have an adhesive point. In addition, the adhesive points could also be arranged in the form of an equilateral triangle around the electronic component part 1, wherein the centroid of this equilateral triangle preferably coincides with the virtual centre point of the lower face 6.

As already mentioned in the introduction, the expression “corner of the electronic component part 1” is understood to mean an area at which the course of an edge of the electronic component part formed between a side face and the lower face 6 changes in such a way that a corner is formed. The corner 10a is therefore formed substantially by the common point of intersection of the side faces 5a and 5d with the lower face 6. Similarly, the corner 10b is formed substantially by the common point of intersection of the side faces 5a and 5b with the lower face 6 (the corners 10c and 10d can be defined similarly via the side faces 5b and 5c and also 5c and 5d and the lower face 6 respectively).

FIG. 2 shows a detail of a sectional illustration of a first variant of an adhesive connection between the electronic component part 1 and the carrier plate 2 in accordance with the line of section AA of FIG. 1. The electronic component part 1 has therein a component part contact face 11 arranged on the lower face 6, which component part contact face contacts, via a layer of solder material 13, a carrier plate contact face 12 arranged therebelow on the surface of the carrier plate 2. The expression “lower face 6” is understood to mean the face of the component part 1 facing towards the carrier plate 2. The upper face 4 of the component part 1 faces away from the carrier plate 2 accordingly. The component part contact face 11 and the carrier plate contact face 12 do not have to be continuous, but may consist of a plurality of individual contact faces in order to produce a plurality of contacts separate from one another. Typically, two or three component part contact faces and carrier plate contact faces corresponding thereto can be provided. The surface of the carrier plate 2 also has, in portions, a coating with a solder stop mask 14 (not illustrated in FIG. 1), which extends to an edge region 15 of the carrier plate contact face 12 and covers this. The adhesive point 3b (similarly to the opposite adhesive point 3a) is located on the solder stop mask 14 within this edge region 15, wherein an edge region formed by the side face 5a and the lower face 6 dips into the adhesive point 3b and is thus connected thereto with contact.

FIG. 3 shows a detail of a sectional illustration of a second variant of an adhesive connection between the electronic component part 1 and the carrier plate 2 in accordance with the line of section AA of FIG. 1, wherein, similarly to FIG. 2, unless specified otherwise, like reference signs describe the same features as in FIG. 1. The variant of the invention shown in FIG. 3 differs from FIG. 2 in that the solder stop mask 14 ends already before the edge region 15 of the carrier plate contact face 12 and the adhesive point 3b (and similarly thereto further adhesive points) is mounted directly in this edge region substantially on the carrier plate contact face 12.

Within the scope of this application the area of the carrier plate contact face 12 not covered by solder material 13 and located in the direct vicinity of the electronic component part 1, typically at a distance of at most 0.07 mm, 0.1 mm, 0.2 mm or 0.5 mm, is understood to be an edge region 15.

Now with reference to FIG. 4 a schematic illustration of a temperature profile is shown, to which the electronic component part 1 is exposed typically before, during and after a reflow soldering process. The electronic component part 1 is firstly heated and reaches a pre-heat zone (by way of example for a duration of 150 seconds at temperatures of up to approximately 160° C.), in which for example heat-curing adhesive points can cure and the solder material 13 does not yet melt, in order to advantageously ensure that the adhesive cures before the solder material loses its holding/adhesive force. In accordance with a defined period of time the temperature is quickly increased (for example within approximately 50 seconds to a temperature of approximately 250° C., which is maintained for approximately 50 seconds) in order to quickly melt the solder material 13 and permanently connect said solder material to the two contact faces 11 and 12. Once a defined period of time has elapsed (for example approximately 100 seconds, which is required for the quick heating and the holding of the temperature of approximately 250° C.), the temperature can then be lowered again. The electronic component part 1 is then permanently electrically, mechanically and/or thermally connected to the carrier plate 2.

FIG. 5 shows an exemplary illustration of a probability distribution function of a radial position error of an electronic component part 1 secured with the aid of the method according to the invention. The arithmetic mean value of this radial position error lies with conventional soldering methods in the order of more than 150 μm. The frequency distribution of the radial position error (deviation in mm) illustrated in FIG. 5 shows a significant maximum in the range between 25 and 50 μm, wherein the maximum position error was 90 μm.

For the sake of completeness it should be noted that the carrier plate 2 of course may have a multiplicity of electronic component parts 1, which thanks to the invention on the one hand can be arranged particularly closely to one another and also in a positionally stable manner. In addition, the technical structure of the described method according to the invention and of the carrier plate 2 according to the invention comprising the at least one component part 1 can be modified in any way obvious to a person skilled in the art.

1. A method for positionally stable soldering of at least one component part contact face (11) of an electronic component part (1) to at least one corresponding carrier plate contact face (12) of a carrier plate (2), wherein the at least one electronic component part (1) has a lower and upper face (6 and 4) and also at least one side face (5a, 5b, 5c, 5d) connecting the lower face to the upper face (6 and 4), wherein the at least one component part contact face (11) is formed on the lower face (6) and the at least one carrier plate contact face (12) at least partly has solder material (13), wherein the electronic component part (1) is an optoelectronic component part, the method comprising:
a) mounting at least two adhesive points (3a, 3b, 8a, 8b, 9a, 9b) on the carrier plate (2), wherein the position of each adhesive point (3a, 3b, 8a, 8b, 9a, 9b) is predefined;
b) fitting the carrier plate (2) with the at least one electronic component part (1), wherein the position of the adhesive points (3a, 3b, 8a, 8b, 9a, 9b) is predefined in step a) in such a way that the at least one electronic component part (1) contacts the at least two adhesive points (3a, 3b, 8a, 8b, 9a, 9b) substantially in an edge region formed by the at least one side face (5a, 5b, 5c, 5d) and the lower face 6 and the at least one component part contact face (11) at least partially overlaps the at least one carrier plate contact face (12);
c) waiting for completion of a curing process of the adhesive points (3a, 3b, 8a, 8b, 9a, 9b) for a predefinable period of time t; and
d) heating the solder material (13) in order to establish an electrical, mechanical and/or thermal connection between the at least one component part contact face (11) and the at least one carrier plate contact face (12).

2. The method of claim 1, wherein the adhesive points (3a, 3b, 8a, 8b, 9a, 9b) are arranged in such a way that a virtual straight line of connection between the adhesive points (3a, 3b, 8a, 8b, 9a, 9b) forms a straight line through the centre point of the lower face (6) of the at least one electronic component part (1).

3. The method of claim 1, wherein the adhesive points (3a, 3b, 8a, 8b, 9a, 9b) are arranged in such a way that an adhesive point (3a, 3b, 8a, 8b, 9a, 9b) is arranged at each corner (10a, 10b, 10c, 10d) of the at least one electronic component part (1).

4. The method of claim 1, wherein a corresponding adhesive point (3a, 3b, 8a, 8b, 9a, 9b) is provided at each corner (10a, 10b, 10c, 10d) of the electronic component part (1).

5. The method of claim 1, wherein three adhesive points (3a, 3b, 8a, 8b, 9a, 9b) are provided, of which the virtual straight lines of connection form an equilateral triangle, wherein the centroid of this equilateral triangle coincides with the centre point of the lower face (6).

6. The method of claim 1, wherein the at least two adhesive points (3a, 3b, 8a, 8b, 9a, 9b) consist of a heat-curing adhesive material, wherein the temperature necessary for the heat curing lies below the melting point of the solder material (13).

7. The method of claim 1, wherein the adhesive points (3a, 3b, 8a, 8b, 9a, 9b) are arranged in positions that are exposed in step c) to a heat curing and in so doing are exposed substantially to identical thermal conditions.

8. The method of claim 1, wherein the volume of the adhesive points (3a, 3b, 8a, 8b, 9a, 9b) is predefinable in step a).

9. The method of claim 1, wherein a solder stop mask (14) applied to the carrier plate surface covers an edge region (15) of the at least one carrier plate contact face (12) and in step a) adhesive points (3a, 3b, 8a, 8b, 9a, 9b) are mounted in this edge region (15) on the solder stop mask (14).

10. The method of claim 1, wherein a solder stop mask (14) applied to the carrier plate surface ends before an edge region (15) of the at least one carrier plate contact face (12) and in step a) adhesive points (3a, 3b, 8a, 8b, 9a, 9b) are mounted in this edge region (15) on the solder stop mask (14).

11. The method of claim 1, wherein the at least one electronic component part (1) has at least two or three component part contact faces (11) and at least two or three corresponding carrier plate contact faces (12).

12. The method of claim 1, wherein the at least one electronic component part (1) is an LED.

13. The method of claim 1, wherein the at least one electronic component part (1) is a surface mounted device (SMD) component part.

14. The method of claim 1, wherein the ratio of the weight of the at least one electronic component part (1) to the electrically effective contact area is less than 50 mg/mm².

15. A carrier plate (2) comprising:
at least one electronic component part (1) having at least one component part contact face (11);
at least one carrier plate contact face (12) corresponding to said component part contact face, wherein the at least one electronic component part (1) has a lower and upper face (6 and 4) and also at least one side face (5a, 5b, 5c, 5d) connecting the lower face to the upper face (6 and 4), wherein the at least one component part contact face (11) is formed on the lower face (6) and the at least one carrier plate contact face (12) at least partly has solder material (13),
wherein the electronic component part (1) is an optoelectronic component part, characterised in that the carrier plate (2) has at least two adhesive points (3a, 3b, 8a, 8b, 9a, 9b), wherein the position of each adhesive point (3a, 3b, 8a, 8b, 9a, 9b) is predefinable, wherein the carrier plate (2) is fitted with the at least one electronic component part (1), wherein the position of the adhesive points (3a, 3b, 8a, 8b, 9a, 9b) can be predefined in such a way that the at least one electronic component part (1) contacts the at least two adhesive points (3a, 3b, 8a, 8b, 9a, 9b) substantially in an edge region formed by the at least one side face (5a, 5b, 5c, 5d) and the lower face (6) and the at least one component part contact face (11) partially overlaps the at least one carrier plate contact face (12), wherein the adhesive points (3a, 3b, 8a, 8b, 9a, 9b) are configured to change from an uncured state receiving the electronic component part (1) into a cured state mechanically stabilising the electronic component part (1), wherein the at least one component part contact face (11) can be electrically, mechanically and/or thermally connected to the at least one carrier plate contact face (12) by heating the solder material (13).

16. The method of claim 13, wherein the SMD component part is one without protruding terminal pins and/or without protruding component part contact faces (11).

17. The method of claim 14, wherein the ratio of the weight of the at least one electronic component part (1) to the electrically effective contact area is less than 10 mg/mm².
